(19) United States
(12) Patent Application Publication
(10) Pub. No.: US 2008/0145978 A1
(43) Pub. Date: Jun. 19, 2008

(54) DEPOSITION OF SILICON GERMANIUM NITROGEN PRECURSORS FOR STRAIN ENGINEERING

(75) Inventor: Ravi Laxman, San Jose, CA (US)

Correspondence Address: AIR LIQUIDE;Intellectual Property, 2700 POST OAK BOULEVARD, SUITE 1800, HOUSTON, TX, 77056, US

(73) Assignee: AIR LIQUIDE ELECTRONICS U.S. LP, Houston, TX (US)

(21) Appl. No.: 11/859,517

(22) Filed: Sep. 21, 2007

Related U.S. Application Data
(60) Provisional application No. 60/870,540, filed on Dec. 18, 2006.

(51) Int. Cl. H01L 21/84; H01L 27/12

(52) U.S. Cl. 438/149; 257/347

(57) ABSTRACT

Methods for making a semiconductor device are disclosed herein. In general, the disclosed methods utilize compounds containing silicon, nitrogen, and germanium. Furthermore, the methods and compositions described are particularly applicable for formation of layers over gate structures or electrodes, which are often used in the manufacture of devices such as transistors. The silicon, nitrogen, and germanium containing compounds may allow stress/strain tuning and engineering of deposited layers over the gate structure.

### CROSS-REFERENCE TO RELATED APPLICATIONS

The present application claims the benefit of U.S. Provisional Application Ser. No. 60/870,540, filed Oct. 18, 2006, herein incorporated by reference in its entirety for all purposes.

### BACKGROUND

1. Field of the Invention

This invention relates generally to the field of semiconductor fabrication. More specifically, the invention relates to a method of depositing silicon and germanium precursors.

2. Background of the Invention

Deposition of dielectric films, such as silicon nitride (Si₃N₄) and silicon dioxide on semiconductor substrates is an important step in the formation of many front end of the line (FEOL) and back end of the line (BEOL) integrated circuit (IC) processes. For example, dielectric films may be used to form gate structures for the manufacture of field effect transistors (FETs), spacers separating adjacent FETs, or sacrificial layers in the dynamic random access memory (DRAM). These films are typically deposited employing a variety of chemical vapor deposition techniques such as chemical vapor deposition, atomic layer deposition, plasma enhanced chemical vapor deposition, and plasma enhanced atomic layer deposition (CVD, ALD, PECVD and PEALD).

Traditionally, silane or dichlorosilane in the presence of ammonia have been used to deposit silicon nitride films over gate structures at relatively high temperatures (>650° C.) at varying chamber pressures. Another leading silicon nitride precursor is bis(t-butylamino) silane, (BTBAS), BTBAS is used in the deposition of silicon nitride without formation of ammonium chloride in a low pressure chemical vapor deposition process at >530° C. Ammonia is introduced separately into the deposition high temperature zone to allow successful deposition. However, materials with lower thermal requirements, scaling down of device dimensions, an increase in chip density and complexity require deposition of silicon nitride at lower temperatures (e.g. <500° C.). For example, nickel silicide and other advanced silicides at <90 nm technology have low thermal thresholds (<400° C.). In view of the above, deposition processes below about <500° C. are desirable.

Additionally, in order to improve the speed of the devices and lower power consumption, researchers have developed methods of introducing strain into epitaxial silicon films. Traditionally, this has involved doping of Ge in epitaxial silicon. At 90 nm technology, strain engineering in epitaxial SiGe films is a well-accepted manufacturing for CMOS devices. This enhances the mobility of charge carriers in the silicon channel and therefore improving speed of the device by increasing the drive currents. SiGe epitaxial layers have been found to increase the channel mobility and improve the speed of the device.

Strained silicon engineering is a technique in which a lattice pattern of silicon atoms is either stretched or compressed to improve the speed at which electrons flow through the silicon. When silicon is allowed to deposit on top of a substrate with atoms spaced farther apart (than in silicon lattice), the atoms in silicon are naturally stretched to align with the substrate atoms underneath—thereby leading to “strained silicon”. Moving these silicon atoms farther apart reduces the atomic forces that interfere with the movement of electrons through the transistors, subsequently resulting in better chip performance and lower energy consumption, e.g. the electrons can flow 70% faster in strained silicon, leading to chips that can be 35% faster in performance. Strained silicon strategy generally involves inserting particular atoms into a silicon lattice. Positive transistors (PMOS) run faster when they are compressed, and negative transistors (NMOS) run faster when they are stretched. This is typically used in the epitaxial SiGe process. Tensile stress increases electron mobility. Both tensile and compressive stress affect hole mobility although tensile does to a lesser extent. However, such techniques have not been applied to gate structures such as in the manufacture of transistors.

The contact etch stop layer process (also known as high stress nitride, over the side wall spacer nitride and contact silicide) involves depositing a strained silicon nitride on top of the contact silicide layer. The applied stress may be compressive or tensile. Strain in silicon and silicon nitride films removes inter-valence and inter-band scattering, and also distorts electron/hole lattice interaction in a way that reduces electron/hole effective mass. Silicon nitride particularly is known to be very difficult to fill its valence due to its rigid structure.

Consequently, there is a need for alternative methods and compositions for low-temperature deposition of stress inducing layers over a gate structure.

### BRIEF SUMMARY

Methods for making a semiconductor device are disclosed herein. In general, the disclosed methods utilize compounds containing silicon, nitrogen, and germanium. Furthermore, the methods and compositions described are particularly applicable for formation of layers over gate structures or electrodes, which are often used in the manufacture of devices such as transistors. The silicon, nitrogen, and germanium containing compounds may allow stress/strain tuning and engineering of deposited layers over the gate structure. Other aspects of the methods will be described in more detail below.

In an embodiment, a method of making a semiconductor device comprises forming a gate structure on to a substrate. The method further comprises forming a layer over at least a portion of the gate structure. The layer comprises a compound containing silicon, germanium, and nitrogen.

In another embodiment, a method of forming a stress-inducing layer over a gate structure comprises disposing the gate structure on to a substrate. In addition, the method comprises providing a silicon precursor and a germanium precursor. At least one of the silicon precursor or the germanium precursor also contains nitrogen. The method also comprises determining a concentration of the germanium precursor to tune the stress of the stress-inducing layer. Moreover, the method comprises reacting the silicon precursor and the concentration of the germanium precursor to form the stress-inducing layer over the gate structure.

In an embodiment, a semiconductor device comprises a substrate. The device also comprises a gate structure disposed on said substrate. In addition, the device comprises a stress inducing layer disposed over at least a portion of said gate structure. The stress inducing layer comprises silicon, germanium, and nitrogen.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a detailed description of the preferred embodiments of the invention, reference will now be made to the accompanying drawings in which:

FIGS. 1A-F schematically illustrates cross-sectional views of semiconductor devices during various manufacturing stage.

### NOTATION AND NOMENCLATURE

Certain terms are used throughout the following description and claims to refer to particular system components. This document does not intend to distinguish between components that differ in name but not function.

In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION OF THE PREFERRED EMBODIMENTS

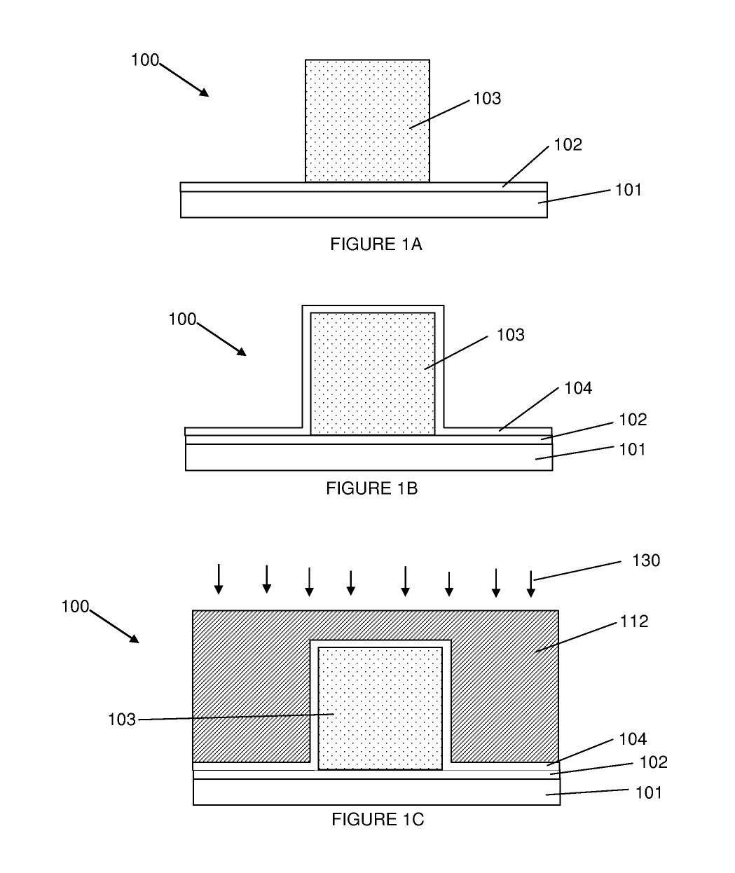

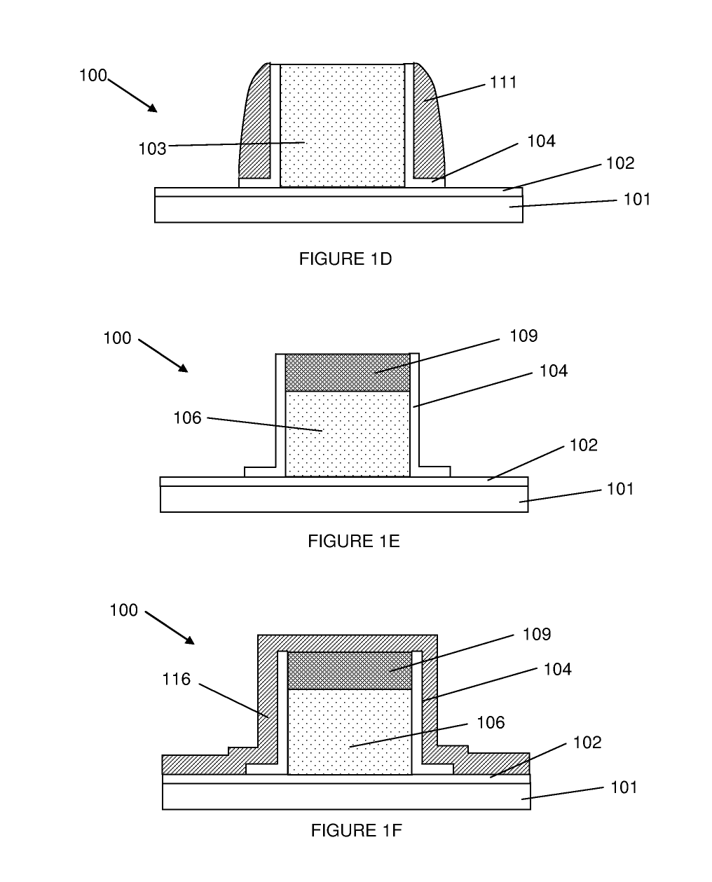

FIGS. 1A-F illustrate a typical semiconductor device 100 in various manufacturing stages to which embodiments of the disclosed methods may apply. Generally, semiconductor device 100 has a substrate layer 101, a semiconductor layer 102 and a gate structure 103. Typically, gate structure 103 is formed on semiconductor layer 102. FIG. 1D also illustrates sidewall spacers 111 disposed on opposite sides of the gate structure 103. Sidewall spacer layers 111 are generally used to protect the sides of the gate structure 103 during additional etching steps in semiconductor fabrication. In addition, sidewall spacer layer 111 may be used as a stress inducing layer. FIG. 1F illustrates a semiconductor device 100 with a contact etch stop layer 116. Contact etch stop layer 116 may be used to induce stress or strain (i.e. a strain inducing layer) to additional dielectric layers deposited on contact etch stop layer 116. As used herein, a stress-inducing layer is a layer which may induce either stress or strain in subsequent (e.g., underlying or overlying layers). In addition, contact etch stop layer 116 serves as a protective layer for underlying layers during an etch process.

In an embodiment, a method of making a semiconductor device comprises providing a substrate layer 101. Substrate layer 101 may comprise without limitation, a bulk silicon substrate, a silicon-on-insulator (SOI) substrate, or a silicon-on-sapphire substrate. However, substrate layer 101 may comprise any appropriate substrate suitable for semiconductor deposition. A typical process flow for forming the semiconductor device 100 as shown in FIG. 1 may comprise the following processes. The substrate 101 and the semiconductor layer 102 may be formed by advanced wafer bond techniques wherein the semiconductor device 100 is to represent an SOI device; or the substrate 101 may be provided without the insulating layer 102, as a bulk semiconductor substrate, wherein the silicon layer 102 may represent an upper portion of the substrate 101; or the semiconductor device 100 may be formed by epitaxial growth techniques.

The method may further comprise forming a gate structure 103 on the substrate 101 as shown in FIG. 1A. Gate structure may be formed by any methods known to those of skill in the art. In an embodiment, gate structure 103 may be formed by depositing a layer of gate material over semiconductor layer 102 by patterning a photoresist layer over gate structure material to define the width of the gate structure and then by etching the layer of gate structure material. Gate structure material may comprise a polysilicon material or any other suitable material. The gate structure 103 may be patterned by sophisticated photolithography and etch techniques in accordance with well-established process recipes.

In an embodiment, an optical image is transferred to a photoresist by projecting a form of radiation, primarily ultraviolet light, through the transparent portions of a mask plate. The solubility of regions of the photoresist exposed to the radiation is altered by a photochemical reaction. The photoresist is then washed with a solvent that preferentially removes resist areas of higher solubility. As such, the now patterned photoresist exposes portions of the polysilicon material to be removed and covers the portion of the polysilicon material to be retained for the gate structure. Those exposed portions of the polysilicon material not protected by photoresist are then etched. The photoresist, being substantially resistant to attack by etchants, remains intact during the etch step, and thereby prevents underlying material from being etched. In this manner, opposed sidewall surfaces for the polysilicon material arranged underneath the photoresist are defined to form a gate structure 103. In addition, gate structure 103 may be formed over semiconductor layer 102 by reactively sputtering metals onto the semiconductor layer. In some embodiments, a liner 104 may be formed over at least a portion of gate structure 103 as shown in FIG. 1B.

Next, the sidewall spacer layers 111 may be formed, wherein the sidewall spacers 111 may be formed as two or more different spacer elements with intermediate implantation processes when a sophisticated laterally profiled dopant concentration is required. To form sidewall spacer 111, a spacer layer 112 of the desired material is formed over gate structure 103 as shown in FIG. 1C. The laterally extending portions of the spacer layer 112 may be removed using an anisotropic etch process 130 such as by reactive plasma etching using a fluorocarbon or fluorohydrocarbon based plasma. As noted above, sidewall spacers 111 serve to protect gate structure 103 during subsequent etch processes. In addition, sidewall spacers 111 may be used to induce stress in underlying or overlying layers.

Thereafter, referring now to FIGS. 1D-E, the sidewall spacer layers 111 may be removed by well-established highly selective etch recipes, wherein the etch chemistry is selected so as to be selective with respect to polysilicon and silicon dioxide, so that the sidewall spacer layers 111, may be efficiently removed substantially without significant material erosion to polysilicon portion 106 of the gate structure 103. Next, metal silicide regions 109 may be formed on the polysilicon portion 106 by depositing a refractory metal, such as nickel, cobalt, molybdenum, tungsten, tantalum, titanium, or combinations thereof and performing an appropriate anneal sequence for initiating a chemical reaction between the silicon and the refractory metal as shown in FIG. 1E.

FIG. 1E schematically shows the semiconductor device 100 after the completion of the above-described process sequence. Hence, the device 100 comprises metal silicide regions 109 on the gate structure 103. Thereafter, a dielectric layer stack is formed for providing a first contact etch stop layer having a specified intrinsic stress.

FIG. 1F schematically shows the semiconductor device 100 with a contact etch stop layer 116 formed over liner 104 and metal region 109. Typically, the gate structure 103 may be embedded in an interlayer dielectric material, over which corresponding metallization layers may be formed to establish the required electrical connections between the individual circuit elements. The interlayer dielectric material may be patterned by means of an anisotropic etch process. Since this anisotropic etch process has to be performed to different depths, a reliable etch stop layer, that is, the contact etch stop layer 116 is provided to reliably control the etch process. Frequently, the interlayer dielectric material is comprised of silicon dioxide and thus the contact etch stop layer 116 may comprise a compound with a good etch selectivity for well-established anisotropic recipes for etching silicon dioxide. Moreover, the compound may be deposited in accordance with well-established deposition recipes, wherein the deposition parameters may be appropriately adjusted for providing a specified intrinsic mechanical stress while nevertheless maintaining the desired high etch selectivity to silicon dioxide. Typically, the compound may be deposited by plasma enhanced chemical vapor deposition (CVD or PECVD) wherein, for example, parameters of the plasma atmosphere, such as bias power supplied to the plasma atmosphere, may be varied in order to adjust the mechanical stress created in the layers as deposited. In a further embodiment, additional contact etch stop layers may be deposited on contact etch stop layer 116 to form more than one contact etch stop layers. Preferably, the etch stop layers comprises the compounds described below.

The layers deposited over gate structure 103 may be of any suitable thickness. More specifically, the contact etch stop layer 116 may have a thickness ranging from about 50 nm to about 150 nm, alternatively from about 30 nm to about 80 nm, alternatively from about 20 nm to about 50 nm.

According to an embodiment, the sidewall spacer layer 111 and/or the contact etch layer 116 comprises a compound containing silicon, germanium, and nitrogen (i.e. a silicon germanium nitrogen compound). More particularly, the compound may have the following formula: Si_{1-(x+y+z)}GeₓN_{y}H_{z}, where the subscripts x, y, and z represent the proportion of germanium, nitrogen, and hydrogen in the compound, respectively. The sum of x, y, z is less than 1, x and y are greater than 0, and z is greater than or equal to 0. In addition, the compound may comprise any percentage of germanium. The amount or percentage of germanium doping in the silicon germanium nitrogen compound may be used to tune the stress in subsequently deposited silicon layers. More specifically, the silicon germanium nitrogen compound may have an atomic percentage of germanium ranging from about 0.1% to about 60%, alternatively from about 0.1% to about 30%, alternatively from about 0.1% to about 20%. Furthermore, the silicon germanium nitrogen compound may have an atomic percentage of nitrogen ranging from about 0.1% to about 40%, alternatively from about 0.1% to about 30%, alternatively from about 0.1% to about 20%.

A mixture or combination of reactants may be used to form the silicon germanium nitrogen compound. In an embodiment, a mixture of a silicon containing precursor and a germanium containing precursor may be used to form the layer (e.g., contact etch stop layer or sidewall spacer layer) of silicon germanium nitrogen compound over the gate structure. Preferably, at least one of the silicon containing precursor and a germanium containing precursor also contains nitrogen. Without being limited by theory, the mixtures of reactants with ligands bonded to the silicon and germanium complexes are chemically similar which may lead to fast exchange of ligands between silicon and germanium and result in a desirable deposition process. Germanium is generally considered a metalloid. Accordingly, the presence of germanium in the deposited compound may catalyze deposition of the sidewall spacers and/or contact etch stop layers over gate structures at lower temperatures because metals may lower the deposition of layers containing silicon dioxide or silicon nitride.

The silicon containing precursor and the germanium containing precursor may be mixed at any suitable ratio. In embodiments, the silicon precursor to germanium precursor ratio may range from about 30% to about 70%, alternatively from about 40% to about 60%, alternatively about 50%.

Any suitable silicon containing precursor may be used. In particular, the mixture or reactants may comprise bis(t-butylamino) silane (SiH₄), trisilylamine, or combinations thereof. In a further embodiment, the silicon-containing precursor may comprise the formula:

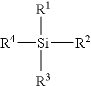

where R¹-R⁴ may each independently comprise an alkylamine, an alkyl group, or hydrogen. R¹-R⁴ may be the same or different from each other. In addition, R¹-R⁴ may comprise alkyl or alkylamine groups that are branched or unbranched and may contain from 1 to 6 carbon atoms.

As with the silicon-containing precursor, the germanium-containing precursor may be any germanium-containing precursor known to those of skill in the art. Germanium is an element that is chemically close to silicon in properties. Specifically, the germanium containing precursor may comprise compounds such as without limitation, bis(t-butylamino) germanium, germane (GeH₄), or combinations thereof. Alternatively, the germanium containing precursor may have the following formula:

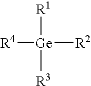

where R¹-R⁴ may each independently comprise an alkylamine, an alkyl group, or hydrogen. R¹-R⁴ may be the same or different from each other. Moreover, R¹-R⁴ may comprise alkyl or alkylamine groups that are branched or unbranched and may contain from 1 to 6 carbon atoms.

The silicon germanium nitrogen compound may be deposited using any deposition methods known to those of skill in the art. For example, the silicon containing precursor and the germanium containing precursor may be mixed or flowed together in a reactor such as without limitation, a cold-wall type reactor, a hot-wall type reactor, a single-wafer reactor, a multi-wafer reactor, or other types of deposition systems under conditions suitable to cause the precursors to react and form the layers. In embodiments, the silicon precursor and the germanium precursor may be deposited or reacted at a pressure ranging from about 0.5 Torr to about 20 Torr, alternatively from about 20 Torr to about 80 Torr, alternatively from about 20 Torr to about 100 Torr. In addition, the temperature of deposition may range from about 200° C. to about 500° C., alternatively from about 100° C. to about 300° C., alternatively from about 100° C. to about 450° C. Furthermore, the deposition of the silicon germanium nitrogen compound may take place in the presence of ammonia, hydrazine, substituted alkylhydrazines, or combinations thereof. Examples of suitable methods include without limitation, low pressure chemical vapor deposition (LPCVD), atomic layer deposition (ALD), plasma enhanced chemical vapor deposition (PECVD), plasma enhanced atomic layer deposition (PE-ALD), or combinations thereof.

While embodiments of the invention have been shown and described, modifications thereof can be made by one skilled in the art without departing from the spirit and teachings of the invention. The embodiments described and the examples provided herein are exemplary only, and are not intended to be limiting. Many variations and modifications of the invention disclosed herein are possible and are within the scope of the invention. Accordingly, the scope of protection is not limited by the description set out above, but is only limited by the claims which follow, that scope including all equivalents of the subject matter of the claims.

The discussion of a reference in the Description of the Related Art is not an admission that it is prior art to the present invention, especially any reference that may have a publication date after the priority date of this application. The disclosures of all patents, patent applications, and publications cited herein are hereby incorporated herein by reference in their entirety, to the extent that they provide exemplary, procedural, or other details supplementary to those set forth herein.

What is claimed is:

1. A method of making a semiconductor device comprising:
a) forming a gate structure on to a substrate;
b) forming a layer over at least a portion of the gate structure, wherein said layer comprises a compound containing silicon, germanium, and nitrogen.

2. The method of claim 1 wherein the substrate comprises a bulk silicon substrate, a silicon-on-insulator (SOI) substrate, or a silicon-on-sapphire substrate.

3. The method of claim 1 further comprising forming a liner over at least a portion of the gate structure before (b).

4. The method of claim 1 wherein the layer is a sidewall spacer layer which covers at least two opposite sides of the gate structure.

5. The method of claim 1 wherein the layer is a contact etch stop layer.

6. The method of claim 1 wherein the compound has the formula: Si_{1-(x+y+z)}GeₓN_{y}H_{z}, wherein the subscripts x, y, and z represent the proportion of germanium, nitrogen, and hydrogen in the compound, respectively, wherein the sum of x, y, z is less than 1, wherein x and y are greater than 0, and z is greater than or equal to 0.

7. The method of claim 1 wherein the germanium is in present in the compound at an atomic percentage ranging from about 0.1% to about 60%.

8. The method of claim 1 wherein (b) comprises forming more than one contact etch stop layer, wherein each contact etch stop layer comprises a compound containing silicon, germanium, and nitrogen.

9. The method of claim 1 wherein (b) comprises reacting a mixture of a silicon precursor and a germanium precursor to form the layer, wherein at least one of the silicon compound and the germanium compound also contains nitrogen.

10. The method of claim 8 wherein the silicon precursor comprises bis(t-butylamino)silane, silane (SiH₄), trisilylamine, or combinations thereof.

11. The method of claim 8 wherein the silicon precursor has the formula: 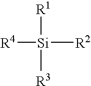
wherein R¹-R⁴ may each independently comprise an alkylamine, an alkyl group, or hydrogen, wherein R¹-R⁴ may be the same or different from each other, and wherein R¹-R⁴ may comprise alkyl or alkylamine groups that contain from 1 to 6 carbon atoms.

12. The method of claim 8 wherein the germanium precursor comprises bis(t-butylamino)germanium, germane (GeH₄), or combinations thereof.

13. The method of claim 8 wherein the germanium precursor has the formula: 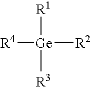
wherein R¹-R⁴ may each independently comprise an alkylamine, an alkyl group, or hydrogen, wherein R¹-R⁴ may be the same or different from each other, and wherein the alkyl or alkylamine groups may contain from 1 to 6 carbon atoms.

14. The method of claim 8 wherein the mixture of the silicon precursor and the germanium precursor comprises silicon precursor to germanium precursor ratio ranging from about 40% to about 60%.

15. The method of claim 1 wherein (b) comprises using chemical vapor deposition, atomic layer deposition, plasma enhanced chemical vapor deposition, and plasma enhanced atomic layer deposition to deposit the layer over the gate structure.

16. A method of forming a stress-inducing layer over a gate structure comprising:
a) disposing the gate structure on to a substrate;
b) providing a silicon precursor and a germanium precursor, wherein at least one of the silicon precursor and the germanium precursor also contains nitrogen;
c) determining a concentration of the germanium precursor to tune the stress of the stress-inducing layer; and
d) reacting the silicon precursor and the concentration of the germanium precursor to form the stress-inducing layer over the gate structure.

17. The method of claim 14 wherein (d) comprises reacting the silicon precursor and the concentration of the germanium precursor at a pressure ranging from about 0.5 Torr to about 20 Torr.

18. The method of claim 14 wherein (d) comprises reacting the silicon precursor and the concentration of the germanium precursor at a temperature ranging from about 200° C. to about 500° C.

19. A semiconductor device comprising:
a substrate;
a gate structure disposed on said substrate; and
a stress inducing layer disposed over at least a portion of said gate structure, wherein said stress inducing layer comprises silicon, germanium, and nitrogen.

20. The semiconductor device of claim 19 wherein said stress inducing layer is a sidewall spacer layer disposed on at least two opposite sides of said gate structure.

21. The semiconductor device of claim 20 further comprising a liner disposed between said sidewall spacer layer and said gate structure.

22. The semiconductor device of claim 19 wherein said stress inducing layer is a contact etch stop layer.

23. The semiconductor device of claim 19 wherein said stress inducing layer comprises a compound having the formula:
Si_{1-(x+y+z)}GeₓN_{y}H_{z},
wherein the subscripts x, y, and z represent the proportion of germanium, nitrogen, and hydrogen in the compound, respectively, wherein the sum of x, y, z is less than 1, wherein x and y are greater than 0, and z is greater than or equal to 0.

24. The semiconductor device of claim 19 further comprising a metal silicide layer disposed on said gate structure, wherein said stress inducing layer is disposed over said metal silicide layer.

25. The semiconductor device of claim 24 wherein said metal silicide layer comprises nickel, cobalt, molybdenum, tungsten, tantalum, titanium, or combinations thereof.
